(19) United States
(12) Patent Application Publication
(10) Pub. No.: US 2026/0059808 A1
(43) Pub. Date: Feb. 26, 2026

(54) APPARATUS AND METHODS FOR GENERATING SEPARATED SPIN-POLARIZED EXCITON-POLARITON QUASIPARTICLES

(71) Applicant: Nanyang Technological University, Singapore (SG)

(72) Inventors: Rui SU, Singapore (SG); Jie LIANG, Singapore (SG); Chi Hin Timothy LIEW, Singapore (SG)

(21) Appl. No.: 19/039,740

(22) Filed: Jan. 28, 2025

(30) Foreign Application Priority Data
Aug. 22, 2024 (SG) 10202402568P

(51) Int. Cl. H10D 48/00; H01S 5/04; H01S 5/10; H10N 52/00

(52) U.S. Cl. CPC H10D 48/385; H01S 5/041; H01S 5/1042; H10N 52/101

(57) ABSTRACT

Apparatus, systems and methods for generating separated spin-polarized exciton-polariton quasiparticles are disclosed. Apparatus, systems and methods comprise providing a perovskite optical microcavity, incorporating liquid crystal molecules into the perovskite microcavity, and generating one or more polaritons within the microcavity by optically exciting an intersection point corresponding to a point of generation of the polaritons such that the one or more polaritons separate perpendicular to their respective propagation direction.

### CROSS-REFERENCE TO RELATED APPLICATIONS

The present application claims priority to Singapore Application No. 10202402568P filed with the Intellectual Property Office of Singapore on Aug. 22, 2024 and entitled “APPARATUS AND METHODS FOR GENERATING SEPARATED SPIN-POLARIZED EXCITON-POLARITON QUASIPARTICLES,” which is incorporated herein by reference in its entirety for all purposes.

### TECHNICAL FIELD

The present disclosure relates to apparatus, systems, and methods for generating separated spin-polarized exciton-polariton quasiparticles. In particular, the present disclosure relates to apparatus and methods for generating separated exciton-polariton quasiparticles in a microcavity using optical excitation.

### BACKGROUND

The creation and manipulation of spin currents is central to the field of spintronic applications, which may employ the spin degrees of freedom for novel spintronic functionalities. Among the various possibilities, the spin Hall effect serves as a unique pathway, where a transverse pure spin current forms perpendicular to the flow direction of an electrical charge current inside a material. This may allow permanently separated carriers with opposite spins in real space, which may provide the possibility for effective manipulations and implementations towards spintronic devices.

Fundamentally, the interaction of a carrier's spin with its orbital motion, namely, the spin-orbit interaction, serves as the underlying mechanism for the spin Hall effect, including both intrinsic and extrinsic phenomena. The history of the spin Hall effect dates back to the prediction in condensed-matter systems by Dyakonov and Perel 50 years ago, and is recently revived in different kinds of solid-state system, such as paramagnetic metals and semiconductors.

In analogy to electronic systems, the spin Hall effect of light manifesting as the spin-dependent separation or accumulation of photons also received considerable attention due to its huge potential in the optical counterpart of spintronics. Similar to electronic systems, the underlying physics originates from the spin-orbit interaction of light and one of the important prerequisites for spin-optoelectronics is to generate spin-polarized light with high purity.

One promising platform for spin-optoelectronics is the so-called microcavity exciton-polariton system, where spinor quasiparticles form from the hybridization of semiconductor excitons and cavity photons in the strong-coupling regime. They serve as excellent candidates to link condensed-matter systems to photonic systems for designing novel spin-optoelectronic devices, owing to the combined advantages from light and matter.

Essentially, exciton-polaritons can be considered as dressed photons with matter excitation of excitons, which simultaneously provide applied field sensitivity and unique spin properties. In microcavities, the photonic spin-orbit coupling originates from the transverse-electric-transverse-magnetic mode splitting and serves as an artificial magnetic field in momentum space, which has led to various effects, such as the formation of spinor excitations, topological insulators, synthetic gauge fields and optical spin Hall effects. In particular, earlier demonstrations of optical spin Hall effects rely on this artificial magnetic field for the spin relaxation of polaritons propagating in different directions, populated by either resonant Rayleigh scattering or acceleration by a potential. However, continuous polariton spin precession means that polariton spins are not permanently separated; instead, they oscillate with specific spin polarizations appearing only at periodic points over macroscopic distances. Additionally, the achieved polariton spin currents in earlier schemes usually suffer from limited spin polarizations less than 0.5.

Recently, the emergence of synthetic spin-orbit coupling inside microcavities has allowed spin-split bands with a high spin degree in the Rashba-Dresselhaus regime, providing a possible route to tackle the above challenges.

### SUMMARY OF THE INVENTION

Example embodiments disclosed herein demonstrate the polariton spin Hall effect in the Rashba-Dresselhaus regime with CsPbBr₃ perovskite microcavities, where polariton spins with a high degree of 0.88 are permanently separated, without oscillation, as they propagate over microscopic distances of 45 μm at room temperature.

In example embodiments, by introducing liquid crystal (LC) molecules into the CsPbBr₃ perovskite microcavities, embodiments disclosed herein achieve synthetic spin-orbit coupling and reach into the Rashba-Dresselhaus regime with spin-split bands having a high degree of 0.91 in momentum space.

By resonantly exciting at the intersection point of spin-split bands with a linearly polarized beam, polaritons with opposite spins tend to propagate and oppositely separate perpendicular to the flow direction, due to the unique Rashba-Dresselhaus band structure. Furthermore, by tuning the spin-orbit coupling, the polariton spin transport behaviour can be effectively manipulated into an oscillation behaviour under different electrical voltages.

According to a first aspect of the present disclosure a method for generating separated spin-polarized exciton-polariton quasiparticles is provided. The method comprises providing a perovskite optical microcavity, incorporating liquid crystal molecules into the perovskite microcavity, and generating one or more polaritons within the microcavity by exciting or stimulating an intersection point corresponding to a point of generation of the polaritons such that the one or more polaritons separate perpendicular to their respective propagation direction.

In an embodiment, the separated polaritons exhibit opposite spins.

In an embodiment, generating the one or more polaritons comprises exciting or stimulating the microcavity via optical pumping.

In an embodiment, the optical pumping is via a laser.

In an embodiment, the laser is configured to provide photons with an energy of around 2.283 eV (corresponding to wavelength of around 543 nm).

In an embodiment, the perovskite microcavity is formed of CsPbBr₃.

In an embodiment, the polaritons exhibit a high degree of spin polarization (optionally of at least 0.88) as the polaritons propagate.

In an embodiment, the polaritons propagate without oscillation, or without substantial oscillation, over a distance (optionally wherein the propagation distance is at least 45 micrometers).

In an embodiment, the one or more polaritons are generated at room temperature.

In an embodiment, the perovskite microcavity is configured to induce a Rashba-Dresselhaus spin-orbit coupling regime.

In an embodiment, the method further comprises applying an external voltage across the microcavity to manipulate a spin transport or a propagation of the spin-polarized polaritons.

In an embodiment, the liquid crystals are aligned by the applied voltage.

In an embodiment, the alignment of the liquid crystals provides for a controllable optical anisotropy between orthogonally linearly polarized modes of the generated polaritons.

In an embodiment, the method further comprises tuning a spin-orbit coupling of the one or more polaritons to induce oscillation behaviour in a spin transport of the polaritons under the influence of an external voltage.

In an embodiment, the method further comprises providing a pair of distributed Bragg reflectors sandwiching the microcavity and configured to form the optical microcavity.

In an embodiment, the method further comprises providing a pair of transparent conductors sandwiching the microcavity and configured to allow application of a voltage across the microcavity.

In an embodiment, the generated spin-polarized exciton-polaritons are for use in one or more of a spin laser, a spin filter, or a spin logic gate.

According to a second aspect of the present disclosure an apparatus for generating separated spin-polarized exciton polariton quasiparticles is provided. The apparatus comprises an emission layer comprising a perovskite microcavity configured to generate one or more polaritons, a plurality of liquid crystal molecules incorporated within the perovskite microcavity, the liquid crystal molecules configured to induce a Rashba-Dresselhaus spin orbit coupling regime for polaritons, and an excitation or stimulation source configured to provide optical excitation or stimulation at an intersection point corresponding to a point of generation of the polaritons, such that polaritons with opposite spins separate perpendicular to a respective propagation direction of the polaritons (or separate perpendicular to a respective flow direction of the polaritons).

In an embodiment, the liquid crystal molecules are configured to manipulate a spin transport behavior of the one or more polaritons via synthetic spin-orbit coupling.

In an embodiment, the excitation source is a laser.

In an embodiment, the laser is configured to provide photons with an energy of around 2.283 eV (corresponding to wavelength around 543 nm).

In an embodiment, the perovskite microcavity is formed of CsPbBr₃.

In an embodiment, the apparatus is configured to generate polaritons exhibiting a high degree of spin polarization (optionally of at least 0.88) as they propagate.

In an embodiment, the polaritons propagate without oscillation over a distance (optionally wherein the propagation distance is at least 45 micrometers).

In an embodiment, the apparatus is configured to allow generation of the one or more polaritons at room temperature.

In an embodiment, the perovskite microcavity is configured to induce a Rashba-Dresselhaus spin-orbit coupling regime.

In an embodiment, the microcavity comprises a Rashba-Dresselhaus band structure.

In an embodiment, the apparatus further comprises a voltage application means configured to manipulate a spin transport or the propagation of the polaritons within the microcavity.

In an embodiment, the voltage application means are configured to control oscillation behaviour of the generated polaritons by tuning a spin-orbit coupling of the one or more polaritons.

In an embodiment, the apparatus is configured such that the liquid crystal molecules are aligned by an applied voltage from the voltage application means.

In an embodiment, the alignment of the liquid crystals provides for a controllable optical anisotropy between orthogonally linearly polarized modes of the generated polaritons.

In an embodiment, the apparatus generates spin-polarized exciton-polaritons for use in one or more of a spin laser, a spin filter, or a spin logic gate.

In an embodiment, the apparatus further comprises a pair of distributed Bragg reflectors sandwiching the microcavity and configured to form an optical microcavity.

In an embodiment, the distributed Bragg reflectors comprise multiple SiO₂/TiO₂ layers provided on a glass substrate.

In an embodiment, the glass substrate is coated with a transparent conductor for introduction of an external electrical voltage for controlling the orientation of liquid crystal molecules.

In an embodiment, the apparatus further comprises a pair of transparent conductors sandwiching the microcavity and configured to allow application of a voltage across the microcavity.

According to a third aspect of the present disclosure a method for controlling the spin transport behaviour of exciton-polaritons is provided. The method comprises generating one or more spin-polarized exciton-polaritons in a perovskite microcavity, the microcavity incorporating liquid crystal molecules configured to manipulate a spin transport behaviour of the one or more polaritons via synthetic spin-orbit coupling, and optically exciting or stimulating an intersection point corresponding to a point of generation of the polaritons such that the one or more polaritons separate perpendicular to their respective propagation direction, and applying an external electrical voltage across the microcavity to manipulate a spin transport behaviour or the propagation of the one or more polaritons.

In an embodiment, the separated polaritons exhibit opposite spins.

In an embodiment, generating the one or more polaritons comprises exciting the microcavity via optical pumping.

In an embodiment, the optical pumping is via a laser.

In an embodiment, the laser is configured to provide photons with an energy of around 2.283 eV (corresponding to a wavelength of around 543 nm).

In an embodiment, the perovskite microcavity is formed of CsPbBr₃.

In an embodiment, the polaritons exhibit a high degree of spin polarization (optionally of at least 0.88) as the polaritons propagate.

In an embodiment, the polaritons propagate without oscillation or without oscillating substantially over a distance (optionally wherein the propagation distance is at least 45 micrometers).

In an embodiment, the one or more polaritons are generated at room temperature.

In an embodiment, the perovskite microcavity is configured to induce a Rashba-Dresselhaus spin-orbit coupling regime.

In an embodiment, the liquid crystals are substantially aligned by the applied voltage.

In an embodiment, the alignment of the liquid crystals provides for a controllable optical anisotropy between orthogonally linearly polarized modes of the generated polaritons.

In an embodiment, the applying an external electrical voltage comprises tuning a spin-orbit coupling of the one or more polaritons to induce oscillation behaviour in a spin transport of the polaritons under the influence of the external voltage.

In an embodiment, the method further comprises providing a pair of distributed Bragg reflectors sandwiching the microcavity and configured to form an optical microcavity.

In an embodiment, the method further comprises providing a pair of transparent conductors sandwiching the microcavity and configured to allow application of the voltage across the microcavity.

In an embodiment, the generated spin-polarized exciton-polaritons are for use in one or more of a spin laser, a spin filter, or a spin logic gate.

It will be understood that any of the embodiments of the second or third aspects of the present disclosure may be combined with each other or any of the embodiments described in the first aspect of the present disclosure.

### BRIEF DESCRIPTION OF THE DRAWINGS

In the following, embodiments of the present invention will be described as non-limiting examples with reference to the accompanying drawings in which:

FIG. 1a illustrates an example of a perovskite microcavity according to an embodiment of the disclosure;

FIG. 1b illustrates an example of light emission from a single-crystalline perovskite layer according to an embodiment of the disclosure;

FIG. 1c is a graph of energy splittings between orthogonally linearly polarized modes along x and y directions indicated in FIG. 1a;

FIG. 1d is a graph of two split valleys with opposite polarizations and spins arising from an exact resonance condition of apparatus, systems, and methods according to embodiments of the disclosure;

FIGS. 2a-c show graphs of transition behaviors in polariton dispersions according to embodiments of the disclosure;

FIG. 2d and FIG. 2e show graphs of experimental results illustrating polaritons from example embodiments of the disclosure are highly linearly polarized;

FIG. 2f illustrates a graph of experimental results indicating Rashba-Dresselhaus spin-orbit interaction from example embodiments of the disclosure;

FIG. 3a illustrates an example embodiment of a microcavity undergoing optical stimulation, and the resulting polariton spin Hall effect as described herein;

FIG. 3b shows graphs of momentum-space emission at left and right polarization according to example embodiments of the disclosure;

FIG. 3c shows a graph of intersecting spin-split circles with according to example embodiments of the disclosure;

FIG. 3d shows a schematic graph illustrating permanently separated polariton spins in real space according to example embodiments of the disclosure;

FIG. 3e shows a graph of real-space trajectories of polaritons under different polarizations from example embodiments of the disclosure;

FIG. 3f shows a graph of real-space spectrum showing a high degree of polarization according to example embodiments of the disclosure;

FIG. 3g shows a graph of theoretical calculations of polarization degree as shown in FIG. 3f;

FIGS. 4a-c show graphs of polariton spin state splitting between two modes according to example embodiments of the disclosure;

FIG. 5.1 illustrates dispersion at large momenta of a microcavity according to example embodiments of the disclosure;

FIGS. 5.2a, b, and FIG. 5.3 illustrate experimental results of the occurrence of Rashba-Dresselhaus spin-orbit coupling (RDSOC);

FIG. 5.4a-c illustrate experimental results showing all momentum space imaging in the Rashba-Dresselhaus (RD) regime;

FIGS. 5.5a, b, and FIG. 5.6a-c illustrate experimental results of polarized momentum space imaging;

FIGS. 5.7a-d illustrate experimental results of polariton spin transport properties; and

FIG. 5.8 illustrates theoretical calculations of Stokes parameters in real space according to example embodiments of the disclosure.

### DETAILED DESCRIPTION

Exciton-polaritons-light-matter quasiparticles with spin degrees of freedom and ultrafast dynamics—are a promising platform for spin-based applications. However, an ongoing challenge is the generation and manipulation of high-purity polariton spins over macroscopic distances at room temperature. The invention as disclosed herein related to the concept of separating spin-polarized polaritons. By creating synthetic spin-orbit coupling in perovskite microcavities with liquid crystal molecules, methods, apparatus and systems as described herein demonstrate the polariton spin Hall effect in the Rashba-Dresselhaus regime at room temperature, where spin-polarized polaritons with a high chirality of 0.88 are permanently separated as they propagate over 45 μm. This is further described in Liang, J., Wen, W., Jin, F. et al. Polariton spin Hall effect in a Rashba-Dresselhaus regime at room temperature. Nat. Photon. 18, 357-362 (2024), and Wen, W., Liang, J., Xu, H. et al. Trembling Motion of Exciton Polaritons Close to the Rashba-Dresselhaus Regime, Phys. Rev. Lett. 133, 116903, both of which are incorporated by reference herein.

Additionally, apparatus, systems and methods as disclosed herein further show that the spin transport behaviours of spin-polarized polaritons can be effectively manipulated by external electrical voltages.

The apparatus, systems and methods as disclosed herein represent an important step to generate purer polariton spin currents, paving the way to spin-optoelectronic applications with polaritons, such as spin lasers, spin filters and spin logic gates.

The invention relates to the concept of generating separated spin-polarized exciton-polariton quasiparticles. Various apparatus, systems, and methods are provided for generating separated spin-polarized exciton-polariton quasiparticles as described herein.

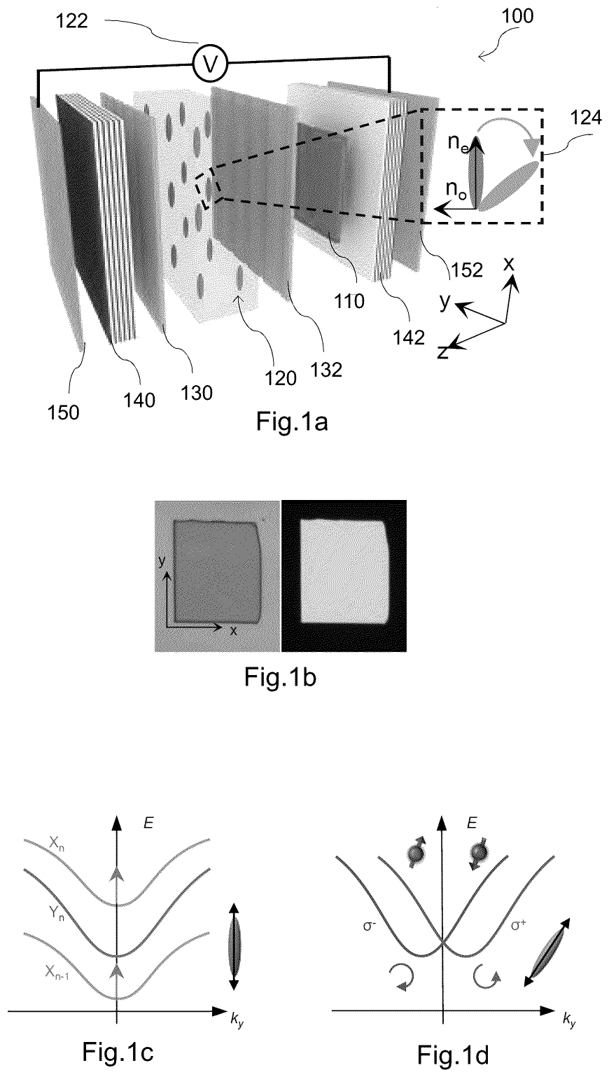

For example, in a first embodiment a method is described for generating separated spin-polarized exciton-polariton quasiparticles. The method comprises providing a perovskite optical microcavity, such as microcavity 100 illustrated in FIG. 1a, including a perovskite layer 110. Liquid crystal molecules 120 are incorporated into the perovskite microcavity 100, to provide for modification of polariton propagation. The method comprises generating one or more polaritons within the microcavity 100 by exciting or stimulating an intersection point corresponding to a point of generation of the polaritons, such that the one or more polaritons separate perpendicular to their respective propagation direction.

In an embodiment, the one or more polaritons are generated at room temperature, and the separated polaritons exhibit opposite spins as demonstrated in experimental results detailed below.

It will be understood that in example embodiments, the incorporated liquid crystal molecules 120 could be replaced by other materials with similar birefringent properties and tunability as described herein.

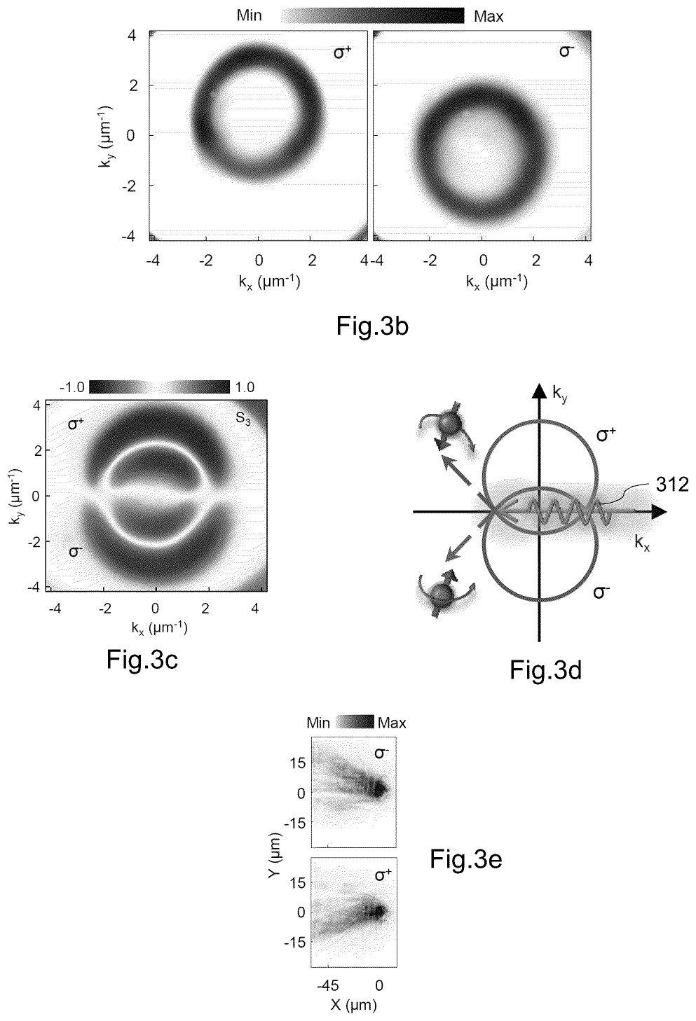

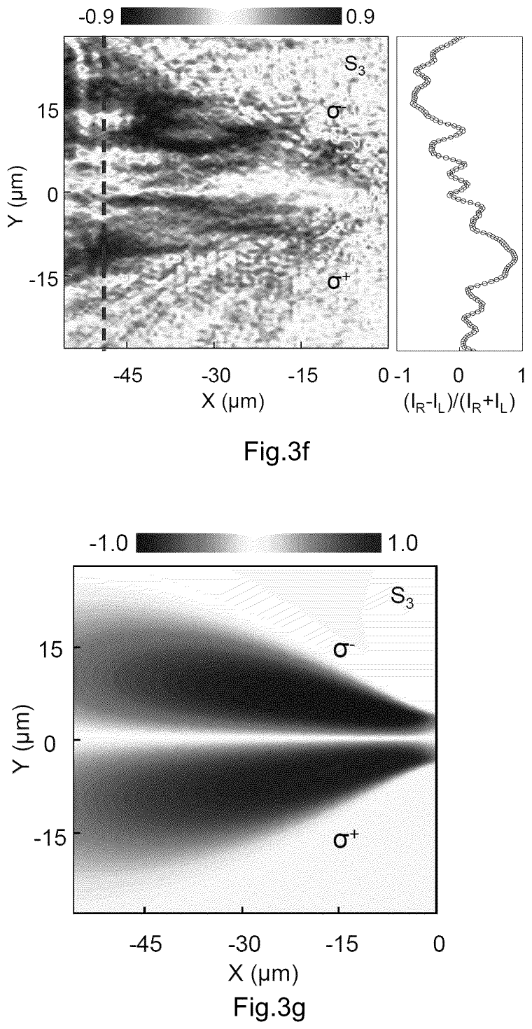

FIG. 3a shows an example embodiment of a microcavity 100/300 as described herein undergoing optical pumping. The microcavity 300 comprises a perovskite layer 310, liquid crystals 320 incorporated into the microcavity 300, and reflectors 340, 342 to provide an optical microcavity 100 as described herein. In an example embodiment, generating the one or more polaritons comprises exciting the microcavity 300 via optical pumping, for example via a laser 312. In an example embodiment, the laser 312 is configured to provide photons with an energy of around 2.283 eV (corresponding to wavelength of around 543 nm). However, it will be understood that in example embodiments the pumping laser 312 wavelength or energy range can fall within a broad range of wavelengths or energy levels sufficient to provide the excitation as described herein.

In an embodiment, the perovskite microcavity 100/300 is formed of CsPbBr₃. However, it will be understood that in example embodiments the microcavity 100/300 can be formed of any other semiconductor material that can show exciton polariton effects as described herein.

FIG. 3a illustrates polariton flow direction or propagation 314, and polariton separation 316. In an example embodiment, the polaritons exhibit a high degree of spin polarization as the polaritons propagate. For example, experimental results detailed below outline a spin polarization of 0.88. Further, in an example embodiment the polaritons propagate without oscillation, or without substantial oscillation, over a significant distance. For example, in experimental results detailed below, the propagation distance is at least 45 micrometers.

In an embodiment, the perovskite microcavity 100/300 is configured to induce a Rashba-Dresselhaus spin-orbit coupling regime as described in the results section below.

Turning back to FIG. 1a, in an example embodiment, applying an external voltage 122 across the microcavity 100 can manipulate a spin transport or a propagation of the spin-polarized polaritons. For example, the liquid crystals 120 may be aligned by the applied voltage 122, as shown inset at 124 which may provide for a controllable optical anisotropy between orthogonally linearly polarized modes of the generated polaritons. In an example embodiment, tuning a spin-orbit coupling of the one or more polaritons can be accomplished, to induce oscillation behaviour in a spin transport of the polaritons under the influence of the external voltage 122 across the microcavity 100.

In an example embodiment, the microcavity 100 may comprise a pair of distributed Bragg reflectors 140, 142 sandwiching the microcavity 100 and configured to form the optical microcavity 100. Further, a pair of transparent conductors 150, 152 may be provided to sandwich the microcavity 100 and allow application of the voltage 122 across the microcavity 100.

It will be understood that the generated spin-polarized exciton-polaritons may have applications in one or more of a spin laser, a spin filter, or a spin logic gate.

As shown in FIG. 1a, in an example embodiment an apparatus 100 for generating separated spin-polarized exciton polariton quasiparticles is provided. The apparatus 100 comprises an emission layer comprising a perovskite microcavity 110 configured to generate one or more polaritons, a plurality of liquid crystal molecules 120 incorporated within the perovskite microcavity, the liquid crystal molecules 120 configured to induce a Rashba-Dresselhaus spin orbit coupling regime for polaritons, and an excitation or stimulation source (312 as shown in FIG. 3a) configured to provide optical excitation or stimulation at an intersection point corresponding to a point of generation of the polaritons, such that polaritons with opposite spins separate perpendicular to a respective propagation direction 314 of the polaritons (or separate perpendicular 316 to a respective flow direction 314 of the polaritons, wherein the flow direction may arise as a result of an applied voltage across the microcavity as described herein).

In an embodiment, the liquid crystal molecules 120 are configured to manipulate a spin transport behavior of the one or more polaritons via synthetic spin-orbit coupling.

In an embodiment, the excitation source 312 is a laser. The laser may be configured to provide photons with an energy of around 2.283 eV (corresponding to wavelength around 543 nm). However, it will be understood that in example embodiments the pumping laser 312 wavelength or energy range can fall within a broad range of wavelengths or energy levels sufficient to provide the excitation as described herein.

In an embodiment, the perovskite microcavity 100/300 is formed of CsPbBr₃. However, it will be understood that in example embodiments the microcavity 100 can be formed of any other semiconductor material that can show exciton polariton effects as described herein.

As demonstrated in experimental results below, the apparatus 100/300 may be configured to generate polaritons exhibiting a high degree of spin polarization (optionally of at least 0.88) as they propagate 314. Further, the polaritons propagate without oscillation over a significant distance, experimentally demonstrated as a propagation distance of at least 45 micrometers.

The apparatus 100/300 may be configured to allow generation of the one or more polaritons at room temperature, and the perovskite microcavity 100/300 may be configured to induce a Rashba-Dresselhaus spin-orbit coupling regime. In an example embodiment, the microcavity 100/300 comprises a Rashba-Dresselhaus band structure.

Turning back to FIG. 1a, in an example embodiment, the apparatus 100 further comprises a voltage application means 122 configured to manipulate a spin transport or the propagation of the polaritons within the microcavity 100. The voltage application means 122 are configured to control oscillation behaviour of the generated polaritons by tuning a spin-orbit coupling of the one or more polaritons. For example, the apparatus 100 may be configured such that the liquid crystal molecules 120 are aligned by an applied voltage from the voltage application means 122 as shown inset at 124. In an example embodiment, the alignment of the liquid crystals 120 provides for a controllable optical anisotropy between orthogonally linearly polarized modes of the generated polaritons.

In an embodiment, the apparatus generates spin-polarized exciton-polaritons for use in one or more of a spin laser, a spin filter, or a spin logic gate.

In an example embodiment, the apparatus further comprises a pair of distributed Bragg reflectors 140, 142 sandwiching the microcavity 100 and configured to form an optical microcavity 100.

In an example embodiment, the apparatus 100 further comprises a pair of transparent conductors 150, 152 sandwiching the microcavity and configured to allow application of a voltage 122 across the microcavity 100. In an example embodiment, the distributed Bragg reflectors 140, 142 comprises one or more SiO₂/TiO₂ alternating layers provided on a substrate 150, 152 (such as a glass substrate), where the substrate 150, 152 may be coated with a transparent conductor to provide for introduction of an external electrical voltage 122 for controlling the orientation of liquid crystal molecules 120 as described herein.

In an example embodiment, a method for controlling the spin transport behaviour of exciton-polaritons is provided. The method comprises generating one or more spin-polarized exciton-polaritons in a perovskite microcavity, such as microcavity 100 as shown in FIG. 1a, where the microcavity 100 incorporates liquid crystal molecules 120 configured to manipulate a spin transport behaviour of the one or more polaritons via synthetic spin-orbit coupling, and optically exciting or stimulating an intersection point corresponding to a point of generation of the polaritons (as shown in FIG. 3a) such that the one or more polaritons separate perpendicular to their respective propagation direction 314, and applying an external electrical voltage 122 across the microcavity to manipulate a spin transport behaviour or the propagation of the one or more polaritons.

In an example embodiment, the separated polaritons exhibit opposite spins and are generated by exciting the microcavity via optical pumping 312 as shown in FIG. 3a. In an example embodiment, the optical pumping 312 is via a laser, which may be configured to provide photons with an energy of around 2.283 eV (corresponding to a wavelength of around 543 nm).

As outlined herein, in an example embodiment, the liquid crystals 120 are substantially aligned by the applied voltage 122, which may provide for a controllable optical anisotropy between orthogonally linearly polarized modes of the generated polaritons. In an example embodiment, the applying an external electrical voltage 122 comprises tuning a spin-orbit coupling of the one or more polaritons to induce oscillation behaviour in a spin transport of the polaritons under the influence of the external voltage 122.

In an embodiment, the method further comprises providing a pair of distributed Bragg reflectors 140, 142 sandwiching the microcavity 100 and configured to form an optical microcavity 100. The method may further comprise providing a pair of transparent conductors 150, 152 sandwiching the microcavity 100 and configured to allow application of the voltage 122 across the microcavity 100.

In example embodiments, methods and apparatus described herein may achieve permanent separation of polariton spins in real space (in-plane direction). Such high-purity polariton spins as demonstrated (up to 0.9) may be able to propagate along in-plane direction for a significant distance, experimentally identified as ˜45 μm. Accordingly, the high purity polariton spins achieved by methods and apparatus described herein can potentially serve as information carriers, which may be advantageous for on-chip optospintronic applications towards information processing. The permanent separation of high-purity polariton spins has not been previously achieved, as earlier work involves a mixing of different spins over long distances. The achievement of separated polaritons and high purity polariton spin may be a result of the specific methods and apparatus configurations as disclosed herein, for example by pumping the crossing point in the unique bandstructure from the liquid-crystal filled microcavity as described herein.

Experimental results demonstrating Rashba-Dresselhaus spin-orbit coupling in a perovskite microcavity are set out below.

To achieve Rashba-Dresselhaus spin-orbit coupling (RDSOC), in an example embodiment an experiment was conducted to produce a structure 100, as set out in FIG. 1a, comprising introducing LC molecules 120 into a CsPbBr₃ perovskite microcavity 110, which have been demonstrated to sustain robust polariton condensation and topological polariton edge states at room temperature.

A schematic of an experimental device structure is shown in FIG. 1a which comprises a bottom distributed Bragg reflector (DBR) 140 spin coated with a poly(methyl methacrylate) (PMMA) layer 130, LC molecules 120, a CsPbBr₃ perovskite microplate 110 spin coated with another PMMA layer 132 and a top DBR 142.

In an example embodiment, the DBRs are fabricated by evaporating 10.5 pairs of SiO₂/TiO₂ layers onto a glass substrate 150 coated with a 150-nm-thick layer of transparent indium tin oxide, which allows the introduction of external electrical voltages 122 for controlling the orientation of LC molecules 120.

A van der Waals epitaxy technique may be employed to synthesize the single-crystalline perovskite layer 110. In an example embodiment as shown in FIG. 1b, the structure exhibits a rectangular shape and bright green emission. FIG. 1b illustrates optical microscopy and corresponding photoluminescence images of a CsPbBr₃ microplate after the transfer process under white (left image) and blue (right image) light from a halogen lamp, respectively. The x and y axes are shown in FIG. 1b, and the scale bars are 20 μm.

In an example embodiment, the introduction of birefringent LC molecules 120 allows for realizing synthetic spin-orbit coupling in microcavities such as 100 as disclosed herein.

As shown in FIG. 1a, without an external voltage 122, the optical long axis of the birefringent LC molecules 120 will initially tend to align along the rubbing direction of x, as shown at inset 124. Due to refractive-index anisotropy along the long and short axes of the birefringent LC molecules 120 in the x-y plane (Δn(U=0)=nₑ−nₒ=0.23), an optical anisotropy may arise, leading to energy splittings between orthogonally linearly polarized modes along the x and y directions. This is illustrated in FIG. 1c, which shows a schematic of lower polariton dispersions with orthogonally linearly polarized modes without an external voltage. As observed in FIG. 1c, only the X-linearly polarized modes blueshift with an increasing voltage (indicated by the arrows on axis E).

When applying an external voltage 122 into the apparatus 100, the birefringent LC molecules 120 rotate towards the electric-field direction in the x-z plane, leading to a controllable optical anisotropy between the orthogonally linearly polarized modes. Consequently, with the increase in external voltage 122, the X-linearly polarized modes tend to shift towards higher energy, whereas the Y-linearly polarized modes remain fixed, as shown in FIG. 1c.

When two orthogonally linearly polarized modes with opposite parity (Xₙ₋₁, Yₙ) are brought into resonance, an effective RDSOC will arise, in analogy to the Rashba-Dresselhaus Hamiltonian contributed by simultaneous Rashba and Dresselhaus fields with equal strength.

The two-dimensional effective Hamiltonian can be written as:

$$\hat{ℋ} = ( \begin{matrix}{\hat{ℋ}}_{+} & Δ {e}^{i θ} \\ Δ {e}^{- i θ} & {\hat{ℋ}}_{-}\end{matrix} ) , \qquad ( 1 )$$

where the Hamiltonians acting on polaritons with circular polarization are

$${\hat{ℋ}}_{\pm } = - \frac{{ℏ}^{2}}{2 m} ( \frac{{\partial }^{2}}{\partial {x}^{2}} + \frac{{\partial }^{2}}{\partial {y}^{2}} ) \pm 2 i α \frac{\partial }{\partial y} . \qquad ( 2 )$$

Here m is the polariton effective mass, a is the RDSOC interaction strength and the off-diagonal terms describe the most general spin splitting of magnitude A. The latter can be taken as independent of the wavevector close to resonance.

It will be understood that this experimental example model differs from those described elsewhere by the presence of phase shift θ. This shift phenomenologically accounts for the fact that excitons in the perovskite layer 110 are coupled to three-dimensional optical modes in the LC 120 and the polarization of these modes is position dependent.

FIG. 1d illustrates a schematic of the lower polariton dispersions featured with RDSOC showing that two orthogonally linearly polarized modes with opposite parity are resonant, resulting in spin-split bands. As a result, the linear component of polarization of the photon emitted from the microcavity is rotated with respect to the polarization of the exciton. At exact resonance, Δ=0 the eigenstates are circularly polarized, leading to two split valleys with opposite circular polarizations and spins in momentum space, as illustrated in FIG. 1d, where o⁻ illustrates left-handed circular polarization or spin-down state, and o⁺ illustrates right-handed circular polarization or spin-up state.

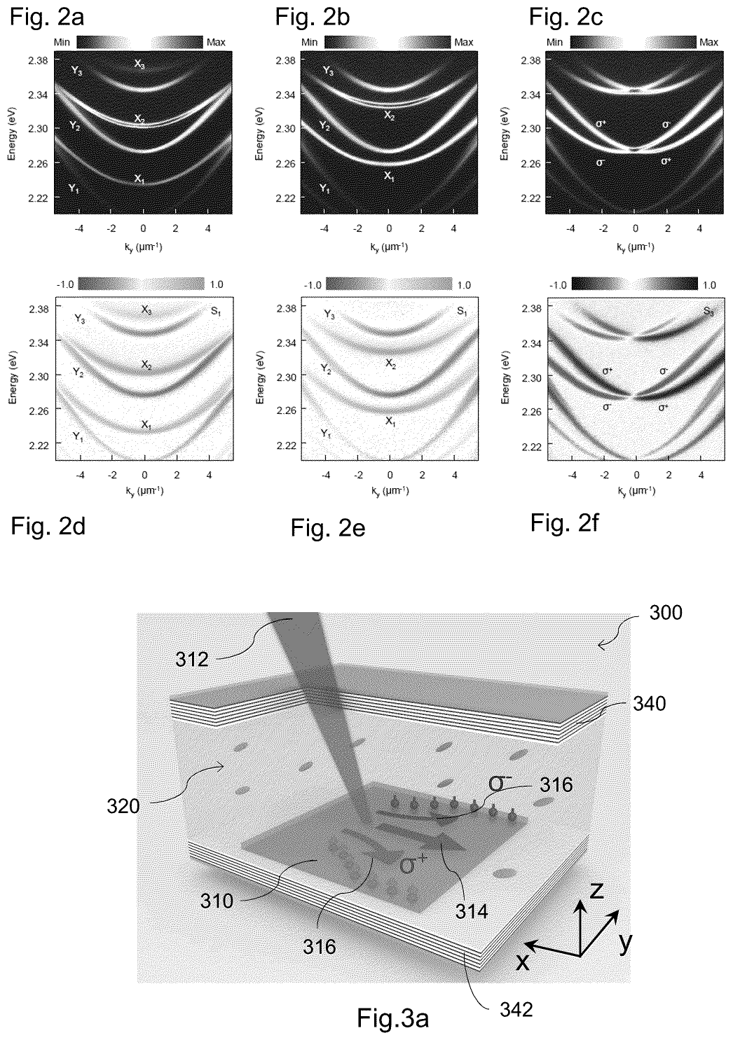

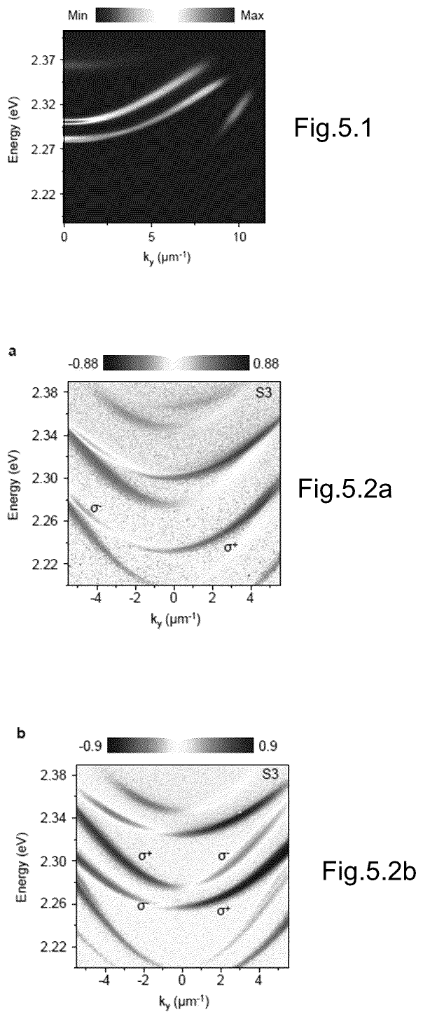

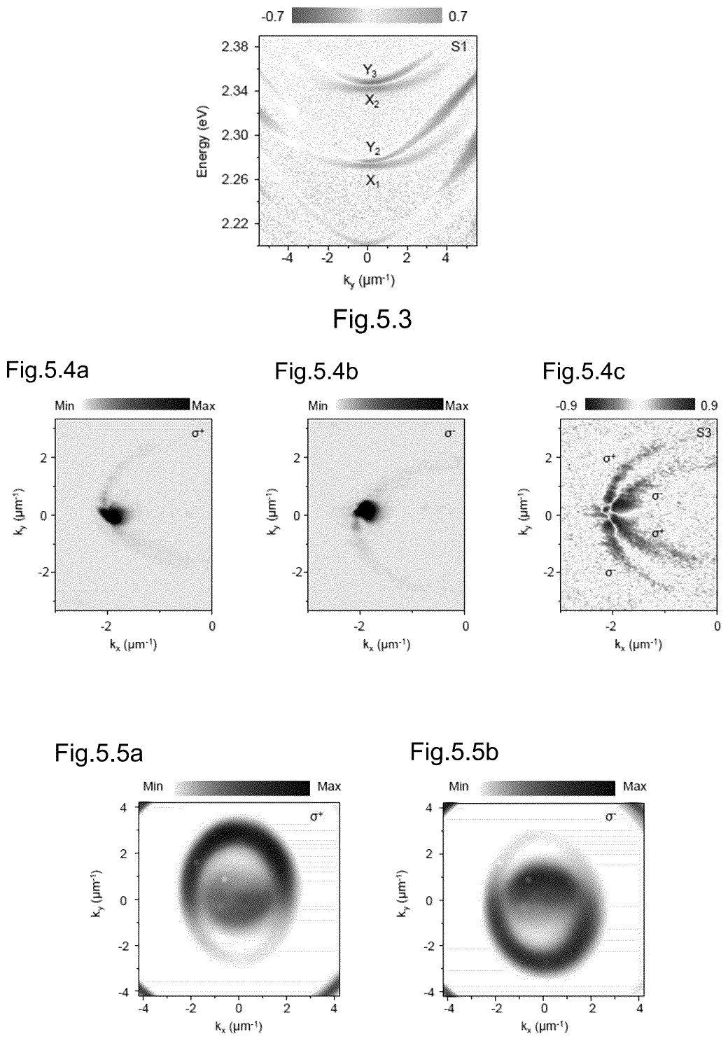

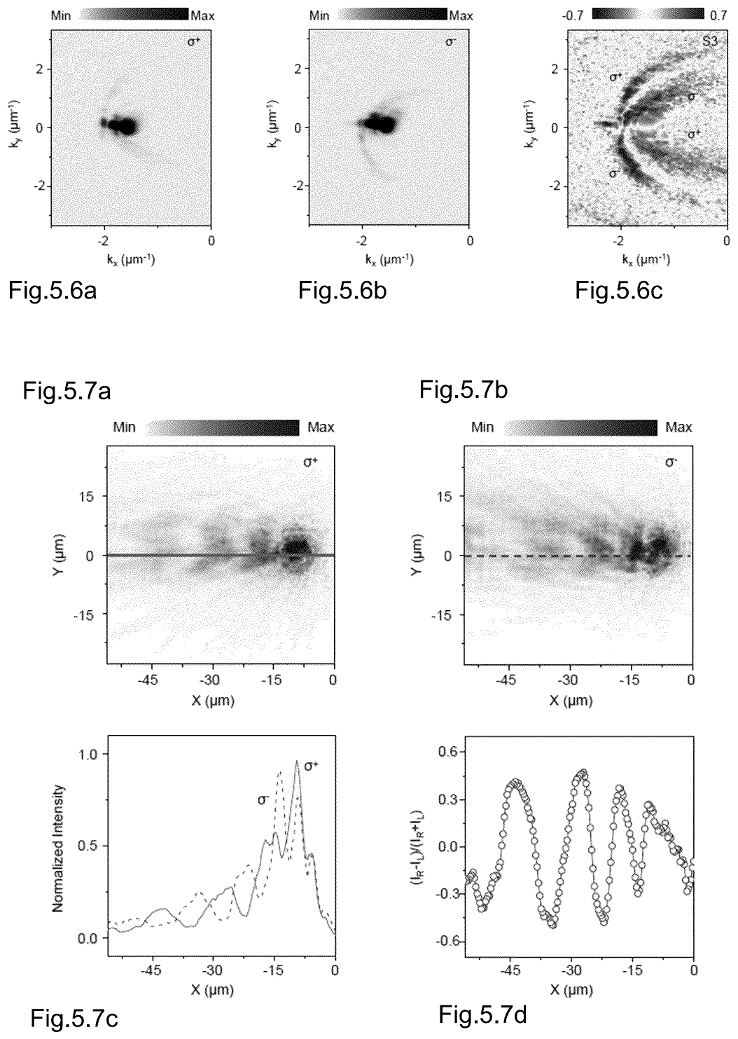

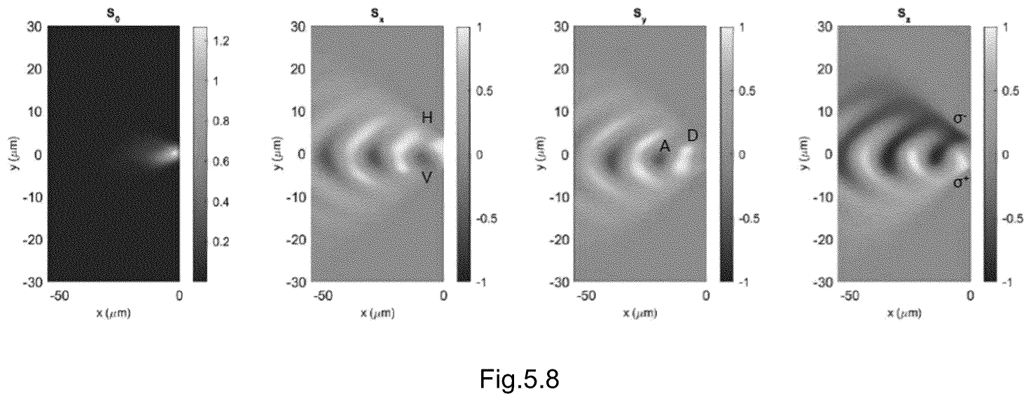

Experimental examples demonstrate the realization of RDSOC in perovskite microcavities, such as 100 or 300 in FIGS. 1a and 3a as described herein, by angle-resolved photoluminescence spectroscopy measurements under external voltages 122. In an example embodiment, a CsPbBr₃ microplate embedded in an LC-filled optical cavity is pumped by a continuous-wave laser with an energy of 2.713 eV and the y axis is aligned to be parallel to the entrance slit of the spectrometer. By changing external voltages, clear transition behaviours in polariton dispersions are observed, as shown in FIG. 2a-c. Further, the flattening of dispersion curvature in typical samples at large momenta suggests a strong light-matter coupling regime between the perovskite exciton and cavity photonic modes, as illustrated in supplementary FIG. 5.1.

FIGS. 2a-c illustrate exciton-polaritons in the RDSOC regime, and show angle-resolved photoluminescence spectra showing multiple dispersions at 2.2 V (2a), 2.6 V (2b) and 3.0 V (2c). The evolution of dispersion clearly shows the blueshifts in the X-polarized modes with an increase in external voltages. FIG. 5.1 illustrates dispersion at much larger momentum of the perovskite-LC microcavity, which confirms the strong coupling regime.

As the polarization of polariton modes is coordinate dependent in LC microcavities, polarization properties are acquired by measuring the polarization of a signal from a front edge of the microcavity. As shown in FIG. 2a, multiple polariton branches with clear energy splitting are observed between X- and Y-linear polarizations at a voltage of 2.2 V.

As the voltage increases, the X-polarized branches X₃, X₂ and X₁ shift towards higher energy, whereas the Y-polarized branches Y₃, Y₂ and Y₁ remained fixed. As a result, the orthogonally polarized modes with opposite parity become near-resonant at 2.6 V as shown in FIG. 2b.

With further increase of the external voltage to 3.0 V, the orthogonally linearly polarized modes of opposite parity (modes X₁ and Y₂; modes X₂ and Y₃) are brought into resonance, and the polariton dispersions are shifted along k_{y}, suggesting the occurrence of RDSOC in the microcavity, as shown in FIG. 2c.

To further demonstrate the realization of RDSOC, the Stokes vector components are measured to analyse their spin behaviours. The experimental results reveal that polaritons are highly linearly polarized with a high degree of 0.91, as shown in FIG. 2d, whereas polaritons show a limited circular polarization degree at 2.2 V, as shown in supplementary FIG. 5.2a.

With further increase of the external bias to 2.6 V, the linear polarization degree S₁ tends to decrease, as shown in FIG. 2e, whereas the circular polarization degree tends to increase to ˜0.85, indicating a transition towards the Rashba-Dresselhaus regime, as shown in supplementary FIG. 5.2b.

FIGS. 2d and 2e illustrate experimental S₁ Stokes parameter at 2.2 V (2d) and 2.6 V (2e), corresponding to dispersion in FIG. 2a and FIG. 2b, respectively. Further, supplementary FIGS. 5.2a and b illustrate experimental S₃ Stokes parameter at 2.2 V (corresponding to FIG. 2a) and 2.6 V (corresponding to FIG. 2b) respectively, suggesting the occurrence of RDSOC.

When the external bias reaches 3.0 V, characteristic spin-split dispersions are observed with a near-unity circular polarization degree S₃ of 0.91, as shown in FIG. 2f. Further, a relatively weak linear polarization degree S₁ is observed, as shown in supplementary FIG. 5.3), which further confirms the realization of RDSOC in the methods and apparatus as described herein.

FIG. 2f illustrates experimental S₃ Stokes parameter at 3.0 V with spin-split bands and near-unit degree, indicating the realization of an effective Rashba-Dresselhaus spin-orbit interaction. Further, supplementary FIG. 5.3 illustrates experimental S₁ Stokes parameter at 3.0 V in the Rashba-Dresselhaus regime.

Experimental results of observations of the spin Hall effect with Rashba-Dresselhaus polaritons are set out below:

In the Rashba-Dresselhaus regime, it is understood that the polariton eigenstates are no longer linearly polarized, but instead they become circularly polarized. In the (kₓ, k_{y}) momentum space, the circular polarization degeneracy is lifted, and the spin bands are shifted along the Rashba-Dresselhaus field (k_{y}), which provides a possibility to achieve the polariton spin Hall effect, as illustrated in FIG. 3a. FIG. 3a illustrates a schematic of spin-polarized polariton separation in real space. The injection of a resonant laser beam 312 acts as a spinless current injection, thus generating the spin Hall current perpendicular to the direction of polariton flow 314.

FIG. 3b illustrates momentum-space emission at 2.283 eV from perovskite microcavities, such as 100/300 as disclosed herein, under o⁺ (left) and o⁻ (right) polarizations, respectively. FIG. 3c illustrates experimental momentum-space spectrum of the S₃ Stokes parameter at 2.283 eV, showing two intersecting spin-split circles.

At higher energy states, it is expected to observe two spin-split circles intersecting with each other in momentum space and the state at this particular intersection point is no longer a pure o⁺ (left)- or o⁻ (right)-polarized state but a mixture of the states. Experimentally, such unique spin properties in the polariton band structure are observed with the methods and apparatus as disclosed herein. A momentum-space emission at 2.283 eV is measured from the perovskite microcavity under o⁺ or o⁻ polarizations. As shown in FIG. 3b, two circles clearly shift along k_{y}, suggesting the occurrence of RDSOC.

Further, the S₃ degree is plotted, as shown in FIG. 3c, which exhibits two characteristic intersecting circles with opposite circular polarizations of o⁺ or o⁻. Although the spins at the intersecting point are not well defined, the group velocities for spin-up and spin-down polaritons are opposite along the k_{y} direction, providing the pathway to permanently separate their polariton spins in real space, as illustrated in FIG. 3d.

In the original optical spin Hall effect, Rayleigh scattering plays an essential role to distribute polaritons around an elastic circle, leading to the exciting combinations of linear polarizations and thus the beating between circularly polarized components as polaritons propagate outwards in real space.

In the experimental examples, the Rayleigh scattering from disorder understood from the original optical spin Hall effect may play an opposite role to suppress and destroy the effect as a complete redistribution of polaritons around the elastic circles would result in equal numbers of each spin polarization travelling in each direction, leading to vanishing of the effect.

Further, the polariton spin Hall effect under a resonant excitation is explored. As shown in FIG. 3d, a linearly polarized continuous-wave laser 312 at 2.283 eV is employed to resonantly pump the intersection point around (kₓ, k_{y})=(−2 μm⁻¹, 0 μm⁻¹) from the back edge of the microcavity and the polaritons are initially injected along the kₓ direction, serving as the spinless polariton current. FIG. 3d illustrates a schematic of the polariton spin Hall effect in momentum space. A linearly polarized beam 312 resonantly (at energy 2.283 eV) excites the intersection point of two spin circles, giving rise to spin-polarized polariton separation.

The real-space trajectories under o⁺ and o⁻ polarizations are further measured. As shown in FIG. 3e, during their propagation over a macroscopic distance of over 45 μm, it is clearly observed the opposite expansion of polariton current under o⁺ and o⁻ polarizations along the k_{y} direction, suggesting polaritons with opposite spins possess opposite group velocities along the k_{y} direction. FIG. 3e illustrates real-space trajectories by the resonant excitation of 2.283 eV collected under o⁺ (bottom) and o⁻ (top) polarizations.

Additionally, the real-space spectrum as shown in FIG. 3f for circular polarization degree S₃ illustrates a unique behavior with a high degree of ˜0.88, where spin-up and spin-down polaritons are fully separated with respect to the x direction. The observed high circular degree of ˜0.88 is higher than the original optical spin Hall effect of ˜0.5, suggesting a purer polariton spin flow. Such a successful observation with a high degree strongly suggests that Rayleigh scattering caused by the microcavity disorder is relatively weak and does not destroy the polariton spin Hall effect in the demonstrated experimental example scheme. FIG. 3f illustrates experimental real-space spectrum of the S₃ Stokes parameter at 2.283 eV, showing polariton spin separation along the Y axis (left). The vertical linecut (right) of the S₃ distribution in real space clearly shows the reversal of the S₃ sign with respect to y=0 μm.

This unique behaviour is in good agreement with the theoretical calculation shown in FIG. 3g. The observation is in analogy to the spin Hall effect in electronic systems, where a spin current occurs perpendicular to the initial charge current. In contrast to the original optical spin Hall effect with polaritons, the experimental realization prevents the possible oscillation of polariton spins and allows to permanently separate polariton spins over macroscopic distances, which is essential for spin-optoelectronic devices with exciton-polaritons. FIG. 3g illustrates theoretical calculation of the corresponding S₃ distribution in real space.

Experimental results of observations of electrical manipulation of polariton spin Hall transport are set out below:

One of the potential advantages for microcavities with LC molecules, such as those described herein, is the sizable and flexible tunability of the mode properties by external electrical voltages, which may provide a new degree of freedom. Consequently, achieving synthetic spin-orbit coupling in a controlled manner may be possible, leading to the effective manipulation of polariton spin Hall transport. Ideally, the eigenstates are circularly polarized and the polariton spin states are split along the k_{y} direction in the Rashba-Dresselhaus regime, leading to two intersecting spin circles in momentum space, as previously discussed and shown in FIG. 3b.

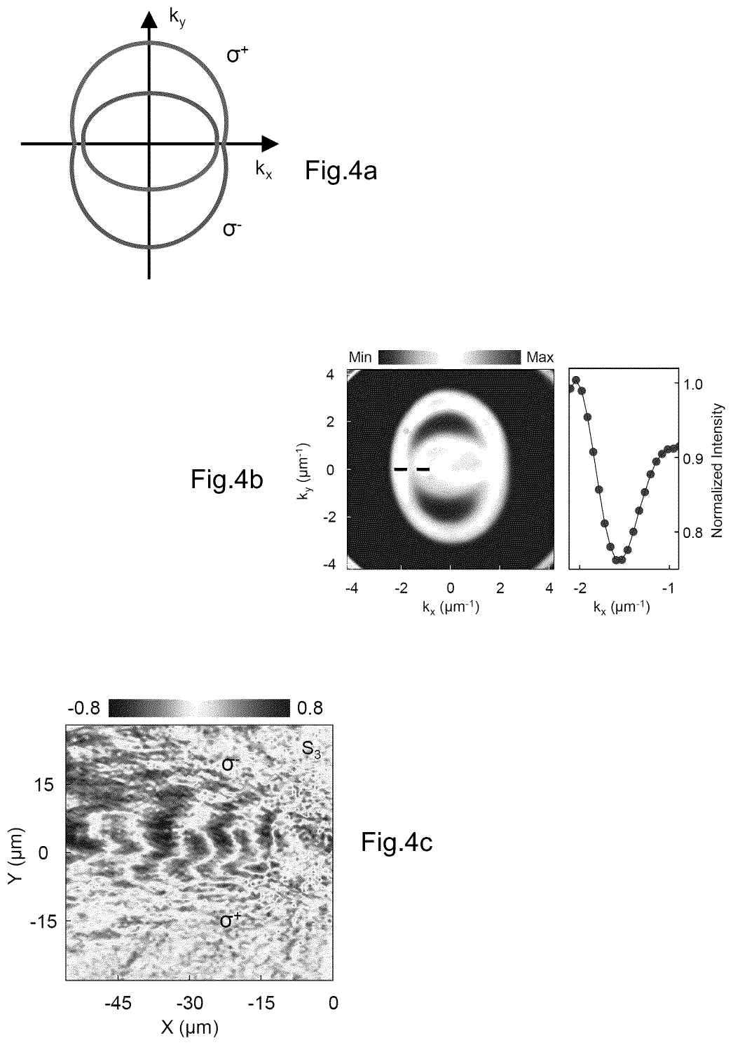

Beyond the exact Rashba-Dresselhaus regime, by changing the external voltage, the degeneracy at the intersecting point may be lifted and an effective splitting may be seen to occur between the two modes, as shown in FIG. 4a and FIG. 4b. FIGS. 4a and 4b illustrate the electrically tunable polariton spin Hall effect as described herein. FIG. 4a illustrates a schematic of the mode splitting in momentum space, resulting in continuous spin precession. FIG. 4b illustrates an energy cross section at 2.283 eV in k_{xy} reciprocal space collected at voltages beyond the Rashba-Dresselhaus regime (left), showing the model splitting (right).

This effective splitting, thus, acts as a direction-dependent effective magnetic field in momentum space, leading to continuous spin precession for polaritons.

Consequently, a distinct spin behavior in real space is observed, as shown in FIG. 4c, which illustrates experimental two-dimensional mapping of S₃ distribution in real space, showing a clear oscillation behaviour under the conditions corresponding to those shown in FIG. 4b. In example embodiments, an oscillation of spin-up and spin-down polaritons occurs. Similar behaviour may be observed in GaAs systems, however these operate at cryogenic temperatures, whereas the experiments described herein operate at room temperature.

Supplementary FIG. 5.7 illustrates a distinct spin behavior in real space, showing polariton spin transport properties beyond the Rashba-Dresselhaus (RD) regime. FIG. 5.7a and FIG. 5.7b respectively illustrate right-handed and left-handed circularly polarized real space imaging under resonant excitation. FIG. 5.7c illustrates intensity spatial distribution along linecut in FIG. 5.7a and FIG. 5.7b, showing solid line for FIG. 5.7a and dashed line for FIG. 5.7b. FIG. 5.7d illustrates corresponding linecut S₃ spatial distribution, clearly showing the oscillation behaviors as described herein.

Details of fabrication of an example embodiment of a CsPbBr₃ perovskite microcavity, such as microcavity 100 in FIG. 1a, with LC molecules 120 are provided below:

Turning to FIG. 1a, in an example embodiment the top and bottom DBRs 140, 142 are prepared by evaporating 10.5 pairs of TiO₂/SiO₂ onto indium tin oxide (150 nm)/glass substrates 150, 152 with an electron-beam evaporator (Cello 50D). The 140 nm-thick CsPbBr₃ single crystal 110 may be synthesized via a chemical vapour phase deposition method, and then transferred onto the bottom DBR 142 through a dry-transfer process with Scotch tape. Thin layers of 60 nm PMMA 130, 132 are spin coated on both perovskite layer 110 and top DBR 140, acting as aligning layers for the LC 120. Then, the spin-coated PMMA layers 130, 132 are rubbed with a rubbing machine for the alignment of LC molecules 120. The optical cavity 100 is fabricated by bonding the top and bottom substrates 150, 152, containing the DBR layers 140, 142, PMMA layers 130, 132, and perovskite crystal layer 110 respectively, with an ultraviolet adhesive (NOA 65) under a press tool that controls the thickness of the LC cavity 120. Finally, the cavity 120 is filled with a birefringent nematic LC E7 (Δn=0.23, nₑ=1.76 and nₒ=1.53 at 532 nm) by capillary force with a pipette close to its interspace.

In an example embodiment, optical spectroscopy characterizations of the microcavity are detailed below. The momentum-space and real-space photoluminescence characterizations are performed using an angle-resolved spectroscopy setup with the Fourier imaging configuration. The optical signal of the fabricated perovskite-LC microcavity 100 is collected through a ×50 objective (numerical aperture, 0.55) and detected by a 550-mm-focal-length spectrometer (Horiba iHR550) with a grating of 600 lines mm⁻¹ and a liquid-nitrogen-cooled charge-coupled device of 256×1,024 pixels. The angle-resolved photoluminescence spectra of the perovskite-LC microcavity 100 is obtained by pumping with an ˜10 μm continuous-wave laser (457 nm) spot. For the observation of the polariton spin Hall effect, the perovskite-LC microcavity is resonantly excited with a linearly polarized continuous-wave laser of 543 nm. An angle-variable lens is employed to adjust the incidence angle of the pumping source. A linear polarizer, a half-wave plate and a quarter-wave plate are placed in the detection path for the investigation of the polarization behaviours. To obtain the polarization states, we calculate the Stokes parameters S1, S2 and S3 as:

$${S}_{1} = \frac{{I}_{H} - {I}_{V}}{{I}_{H} + {I}_{V}} , {S}_{2} = \frac{{I}_{D} - {I}_{A}}{{I}_{D} + {I}_{A}} and {S}_{3} = \frac{{I}_{{σ}^{+}} - {I}_{{σ}^{-}}}{{I}_{{σ}^{+}} + {I}_{{σ}^{-}}}$$

respectively, involving photoluminescence in the horizontal (I_{H}), vertical (I_{V}), diagonal (I_{D}) and antidiagonal (I_{A}) directions, as well as under both circular polarizations (lₒ₊ and lₒ₋).

In an example embodiment, theoretical calculations and simulations of the methods and apparatus disclosed herein are set out below:

The standard driven-dissipative Schrödinger equation was used to model exciton-polaritons in the presence of the Rashba-Dresselhaus Hamiltonian, given by equations (1) and (2):

$$i ℏ \frac{\partial Ψ ( x , y )}{\partial t} = \hat{ℋ} Ψ ( x , y ) - \frac{i Γ}{2} Ψ ( x , y ) + {Fe}^{- \frac{{x}^{2} + {y}^{2}}{{∠}^{2}}} {e}^{{ik}_{p} y} {e}^{- \frac{{t}^{2}}{{τ}^{2}}} ( \begin{matrix}1 \\ 1\end{matrix} ) , \qquad ( 3 )$$

where ψ=(ψ₊, ψ₋)^{T} with ψ₊ and ψ₋ being the wavefunctions of polaritons with + or − spin, respectively; also, Γ is the polariton dissipation rate and F is the amplitude of the X-polarized laser pulse with spot size L, duration τ and wavevector kₚ (along the k_{y} direction). The above Schrödinger equation defines the time dynamics of the system following a laser pulse. From this, the time-averaged intensities

$${I}_{{σ}^{\pm }} = \int {\vert {ψ}_{\pm } ( x , y ) \vert}^{2} dt$$

can be extracted, which then define S₃ in the same way as that used in the experiment. The most important parameters used to construct the data in FIG. 3g were α=1 meV μm and m=2.3×10⁻⁵ mₑ (here mₑ is the electron mass), which were fitted to the experimentally measured dispersion. The results were less sensitive to the other parameters, which were chosen as Γ=1 meV, τ=1 ps, kₚ=−3.8 μm⁻¹ and L=2 μm. FIG. 3g and supplementary FIG. 5.8 show the simulation results.

Supplementary FIG. 5.8 illustrates theoretical calculations of Stokes parameters in real space beyond the RD regime. In addition to the parameters described in the section above, the following parameters are used: Δ=2 meV and θ=π/4. The latter angle was found to give a spin distribution matching more closely the features of the experiment.

Supplementary FIGS. 5.1 to 5.8 are described herein with reference to the below:

### 1. Strong Coupling Regime in a Perovskite-LC Microcavity

Experiments measured the polariton dispersion of a perovskite-LC microcavity at large momentum with a 0.75-NA objective. The result is plotted in FIG. 5.1, which illustrates dispersion bending at high k, verifying the strong light-matter coupling in the fabricated microcavity. The dispersion at much larger momentum of the perovskite-LC microcavity shown in FIG. 5.1 confirms the strong coupling regime as described herein.

### 2. Polarization Properties of Exciton Polaritons in a Perovskite-LC Microcavity

To investigate the polarization property of exciton polaritons in the perovskite-LC microcavity, experiments further characterized the Stokes parameters at different voltages to analyze the pseudospin behaviors. Results shown the circular polarization degree of the microcavity is as low as 0.5 at 2.2 V (FIG. 5.2a), while the eigenmodes mainly represent linear polarization (FIG. 2d) caused by TE-TM splitting. As the external bias increases to 2.6 V, the energy splitting between Xₙ and Yₙ expands, thus Xₙ₋₁ and Yₙ approach and gradually come into resonance at the same time. The circular polarization degree S₃ tends to increase to ˜0.85 (FIG. 5.2b), indicating the emergence of Rashba-Dresselhaus spin orbit coupling (RDSOC). Further, when the external electric field reaches 3.0 V, the linear polarization degree S₁ exhibits a relatively weak value (˜0.6, as shown in FIG. 5.3), while the near resonant Xₙ₋₁ and Yₙ branches enhance the RDSOC, leading to a near unity circular polarization degree S₃ of 0.91 (FIG. 2f). FIGS. 5.2a and 5.2b illustrate experimental S₃ Stokes parameter results at 2.2 V (5.2a) and 2.6 V (5.2b), suggesting the occurrence of RDSOC. FIG. 5.3 illustrates experimental S₁ Stokes parameter at 3.0 V in the Rashba-Dresselhaus (RD) regime.

### 3. Polariton Spin Hall Effect in the Perovskite-LC Microcavity

In order to achieve polariton spin Hall effect, experiments employ a linearly-polarized continuous-wave laser of 2.283 eV to resonantly pump the intersection point in the momentum space around (kₓ, k_{y})=(−2 μm⁻¹, 0 μm⁻¹). As shown in FIGS. 5.4a-c, the circular polarization degree S₃ in the all momentum space is up to 0.89 under resonant excitation condition. FIGS. 5.4a-c illustrate all momentum space imaging under resonant pumping in the RD regime. FIGS. 5.4a and 5.4b respectively illustrate right-handed and left-handed circularly polarized momentum space imaging at 3.0 V under resonant excitation. FIG. 5.4c illustrates corresponding S₃ distribution in the momentum space.

### 4. Electrically Tunable Polariton Spin Hall Effect

Thanks to the sizable and flexible tunability of the cavity modes in a LC microcavity, such as those described herein, the synthetic spin-orbit coupling can be controlled by external electric fields. As the applied bias changed beyond the exact RD regime, a polarization splitting arises between the spin-up and spin-down modes. In momentum space, a gap occurs between the two modes (FIGS. 5.5a and b), giving rise to a direction-dependent effective magnetic field. As shown in FIGS. 5.6a-c, the S₃ Stokes parameter in momentum space decreased to around 0.71 at a voltage beyond the RD regime, leading to different spin transport behaviors. FIGS. 5.5a and b illustrate energy cross section at 2.283 eV in k_{xy} reciprocal space, collected beyond the RD regime. FIGS. 5.5a and 5.5b respectively illustrate right-handed and left-handed circularly polarized momentum space imaging. FIGS. 5.6a-c illustrates all momentum space imaging under resonant pumping beyond the RD regime. FIGS. 5.6a and 5.6b respectively illustrate right-handed and left-handed circularly polarized momentum space imaging under resonant excitation. FIG. 5.6c illustrates corresponding S₃ distribution in the momentum space.

Continuous polariton spin precession is observed beyond the RD regime, as shown in FIGS. 5.7a-d. A clear oscillation happens for both right- and left-handed circular polarizations, resulting incoherent S₃ distribution in the real space. Corresponding theoretical simulations with the model in the main text are presented in FIG. 5.8, which are consistent with the experimental observations as described herein. FIGS. 5.7a-d illustrate polariton spins transport properties beyond the RD regime. FIGS. 5.7a and 5.7b respectively illustrate right-handed and left-handed circularly polarized real space imaging under resonant excitation. FIG. 5.7c illustrates intensity spatial distribution along linecuts shown in FIG. 5.7a and FIG. 5.7b. In FIG. 5.7c, the solid line represents FIG. 5.7a line cut, and the dashed line represents FIG. 5.7b linecut, respectively. FIG. 5.7d illustrates corresponding linecut S₃ spatial distribution, clearly showing the oscillation behaviors as described herein. FIG. 5.8 illustrates theoretical calculations of Stokes parameters in real space beyond the RD regime. In addition to the parameters described herein, parameters Δ=2 meV and θ=π/4 are used. The latter angle was found to give a spin distribution matching more closely the features of the experiments described herein.

Whilst the foregoing description has described exemplary embodiments, it will be understood by those skilled in the art that many variations of the embodiments can be made within the scope and spirit of the present invention.

1. A method for generating separated spin-polarized exciton-polariton quasiparticles, the method comprising:
providing a perovskite optical microcavity;
incorporating liquid crystal molecules into the perovskite microcavity; and
generating one or more polaritons within the microcavity by optically exciting an intersection point corresponding to a point of generation of the polaritons such that the one or more polaritons separate perpendicular to their respective propagation direction.

2. The method of claim 1, wherein the separated polaritons exhibit opposite spins.

3. The method of claim 1, wherein generating the one or more polaritons comprises exciting the microcavity via optical pumping, optionally via a laser configured to provide photons with an energy of around 2.283 eV.

4. The method of claim 1, wherein the one or more polaritons are generated at room temperature.

5. The method of claim 1, wherein the perovskite microcavity is configured to induce a Rashba-Dresselhaus spin-orbit coupling regime.

6. The method of claim 1, further comprising applying an external voltage across the microcavity to manipulate a spin transport or a propagation of the spin-polarized polaritons, optionally wherein the liquid crystals are aligned by the applied voltage, and wherein the alignment of the liquid crystals provides for a controllable optical anisotropy between orthogonally linearly polarized modes of the generated polaritons.

7. The method of claim 1, further comprising tuning a spin-orbit coupling of the one or more polaritons to induce oscillation behaviour in a spin transport of the polaritons under the influence of an external voltage.

8. The method of claim 1, wherein the generated spin-polarized exciton-polaritons are for use in one or more of a spin laser, a spin filter, or a spin logic gate.

9. An apparatus for generating separated spin-polarized exciton polariton quasiparticles, the apparatus comprising:
an emission layer comprising a perovskite microcavity configured to generate one or more polaritons;
a plurality of liquid crystal molecules incorporated within the perovskite microcavity, the liquid crystal molecules configured to induce a Rashba-Dresselhaus spin orbit coupling regime for polaritons; and
an excitation source configured to provide optical excitation at an intersection point corresponding to a point of generation of the polaritons, such that polaritons with opposite spins separate perpendicular to a respective propagation direction of the polaritons or separate perpendicular to a respective flow direction of the polaritons.

10. The apparatus of claim 9, wherein the excitation source is a laser, optionally wherein the laser is configured to provide photons with an energy of around 2.283 eV.

11. The apparatus of claim 9, wherein the perovskite microcavity is formed of CsPbBr₃.

12. The apparatus of claim 9, wherein the apparatus is configured to generate polaritons exhibiting a high degree of spin polarization (optionally of at least 0.88) as the polaritons propagate, optionally wherein the polaritons propagate without oscillation over a distance (optionally wherein the propagation distance is at least 45 micrometers).

13. The apparatus of claim 9, further comprising a voltage application means configured to manipulate a spin transport or the propagation of the polaritons within the microcavity, wherein the voltage application means are configured to control oscillation behaviour of the generated polaritons by tuning a spin-orbit coupling of the one or more polaritons, optionally wherein the apparatus is configured such that the liquid crystal molecules are aligned by an applied voltage from the voltage application means, and wherein the alignment of the liquid crystals provides for a controllable optical anisotropy between orthogonally linearly polarized modes of the generated polaritons.

14. The apparatus of claim 9, further comprising a pair of distributed Bragg reflectors sandwiching the microcavity and configured to form an optical microcavity, optionally wherein the distributed Bragg reflectors comprise one or more SiO₂/TiO₂ layers provided on a glass substrate.

15. The apparatus of claim 9, further comprising a pair of transparent conductors sandwiching the microcavity and configured to allow application of a voltage across the microcavity.

16. A method for controlling the spin transport behaviour of exciton-polaritons, comprising:
generating one or more spin-polarized exciton-polaritons in a perovskite microcavity, the microcavity incorporating liquid crystal molecules configured to manipulate a spin transport behaviour of the one or more polaritons via synthetic spin-orbit coupling;
optically exciting an intersection point corresponding to a point of generation of the polaritons such that the one or more polaritons separate perpendicular to their respective propagation direction; and
applying an external electrical voltage across the microcavity to manipulate a spin transport behaviour or the propagation of the one or more polaritons.

17. The method of claim 16, wherein the separated polaritons exhibit opposite spins.

18. The method of claim 16, wherein generating the one or more polaritons comprises exciting the microcavity via optical pumping optionally via a laser configured to provide photons with an energy of around 2.283 eV.

19. The method of claim 16, wherein the perovskite microcavity is configured to induce a Rashba-Dresselhaus spin-orbit coupling regime.

20. The method of claim 16, wherein the liquid crystals are aligned by the applied voltage, and wherein the alignment of the liquid crystals provides for a controllable optical anisotropy between orthogonally linearly polarized modes of the generated polaritons, optionally wherein the applying an external electrical voltage comprises tuning a spin-orbit coupling of the one or more polaritons to induce oscilation behaviour in a spin transport of the polaritons under the influence of the external voltage.
